(19) United States
(12) Patent Application Publication
(10) Pub. No.: US 2023/0080659 A1
(43) Pub. Date: Mar. 16, 2023

(54) RADIATOR STRUCTURE

(71) Applicant: AMULAIRE THERMAL TECHNOLOGY, INC., New Taipei City (TW)

(72) Inventors: KUO-WEI LEE, New Taipei City (TW); TSUNG-RUEI SUEI, New Taipei City (TW); MIN-HORNG LIU, New Taipei City (TW); TZE-YANG YEH, New Taipei City (TW)

(21) Appl. No.: 17/476,435

(22) Filed: Sep. 15, 2021

(51) Int. Cl. F28F 21/08

(52) U.S. Cl. CPC F28F 21/089

(57) ABSTRACT

A radiator structure is provided. The radiator structure includes a substrate, a first metal coating layer and a second metal coating layer. The first metal coating layer and the second metal coating layer are made of materials different from one another, and are formed on the substrate by different processes. The first metal coating layer is a non-first masking area formed on the substrate by wet processing. The second metal coating layer is a non-second masking area correspondingly formed on the first metal coating layer and the substrate by sputtering. A first masking area and a second masking area are not necessarily the same.

### FIELD OF THE DISCLOSURE

The present disclosure relates to the field of heat dissipation, and more particularly to a radiator structure.

### BACKGROUND OF THE DISCLOSURE

Conventional radiators are mostly made of copper and aluminum alloy, and yet the surface properties of the copper and aluminum alloy are often not suitable for post process or decay in harsh environment (e.g., high temperature or corrosive environment). Therefore, in order to improve the oxidation resistant property and the soldering ability of the copper and aluminum alloy, a surface coating treatment is conventionally performed so that a layer of selected material can be formed on the surface of the radiators. In this way, desired oxidation resistance and/or functionality can be achieved on the surface of the copper and aluminum alloy. However, the conventional coating treatment usually results in an uneven coating, and a selective coating on the surface is usually difficult or inefficient to perform. With the rapid development of modern industry, higher requirements are being placed on a corrosion resistance property and the soldering ability of the radiator, and the conventional radiators often fail to meet such requirements.

### SUMMARY OF THE DISCLOSURE

In response to the above-referenced technical inadequacies, the present disclosure provides a radiator structure.

In one aspect, the present disclosure provides a radiator structure which includes a substrate, a first metal coating layer and a second metal coating layer. The first metal coating layer and the second metal coating each have different materials and are formed on the substrate by different processes. The first metal coating layer is a non-first masking area formed on the substrate by wet processing. The second metal coating layer is a non-second masking area correspondingly formed on the first metal coating layer and the substrate by sputtering. A first masking area and a second masking area are not necessarily the same.

In certain embodiments, the substrate is made of copper, aluminum, copper alloy, or aluminum alloy.

In certain embodiments, the first metal coating layer is made of nickel, nickel alloy, copper, copper alloy, silver, silver alloy, gold, or gold alloy.

In certain embodiments, the first metal coating layer is formed on a surface of the substrate by chemical plating or electroplating.

In certain embodiments, the first masking area is formed by arranging a jig on the substrate, by arranging an electroplating tape on the substrate, or by printing ink on the substrate, so that the first metal coating layer is not formed on the first masking area.

In certain embodiments, the second metal coating layer is made of nickel, nickel alloy, copper, copper alloy, silver, silver alloy, gold, or gold alloy.

In certain embodiments, the second masking area is formed by arranging a jig on the substrate or the first metal coating layer, by arranging an electroplating tape on the substrate or the first metal coating layer, or by printing ink on the substrate or the first metal coating layer, so that the second metal coating layer is not formed on the second masking area.

In certain embodiments, the first masking area and the second masking area do not necessarily overlap with each other, so that the second metal coating layer is formed on a surface of the substrate, on the first metal coating layer, or on both of the surface of the substrate and the first metal coating layer.

In certain embodiments, the substrate has at least one cavity, a water inlet and a water outlet, and the water inlet and the water outlet are correspondingly connected to the at least one cavity.

In certain embodiments, the first metal coating layer is correspondingly formed on a wall surface of the at least one cavity, a periphery of the water inlet, and a periphery of the water outlet.

Therefore, in the radiator structure provided by the present disclosure, by virtue of “the first metal coating layer and the second metal coating layer being made of materials different from one another, and being formed on the substrate by different processes”, “the first metal coating layer being the non-first masking area formed on the substrate by wet processing”, and “the second metal coating layer being the non-second masking area correspondingly formed on the first metal coating layer and the substrate by sputtering, and the first masking area and the second masking area being not necessarily the same”, an oxidation resistance and the aesthetics of the radiator structure can be effectively increased. Further, a corrosion resistance property, a soldering ability, and/or a sintering ability of the radiator structure can be improved, thereby increasing a product life cycle thereof.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a radiator structure having a first masking area formed thereon according to a first embodiment of the present disclosure;

FIG. 2 is a schematic side view of the radiator structure having a second masking area formed thereon according to the first embodiment of the present disclosure;

FIG. 3 is a schematic side view of the radiator structure according to the first embodiment of the present disclosure;

FIG. 4 is a schematic side view of the radiator structure according to a second embodiment of the present disclosure;

FIG. 5 is a schematic side view of the radiator structure having the first masking area formed thereon according to a third embodiment of the present disclosure;

FIG. 6 is a schematic side view of the radiator structure having the second masking area formed thereon according to the third embodiment of the present disclosure;

FIG. 7 is a schematic side view of the radiator structure according to the third embodiment of the present disclosure;

FIG. 8 is a schematic side view of the radiator structure according to a fourth embodiment of the present disclosure;

FIG. 9 is a schematic side view of the radiator structure according to a fifth embodiment of the present disclosure; and

FIG. 10 is a schematic side view of the radiator structure according to a sixth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way.

Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

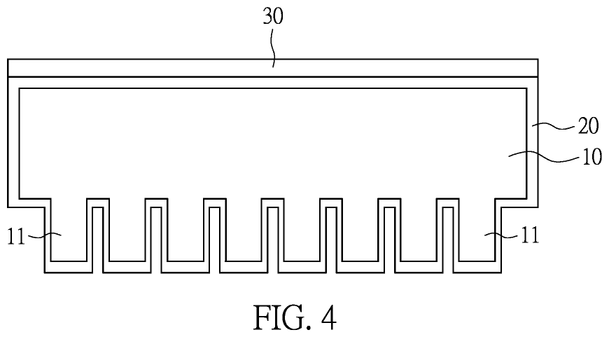

Reference is made to FIG. 1 to FIG. 3, in which a first embodiment of the present disclosure is shown. The first embodiment of the present disclosure provides a radiator structure, which includes a substrate 10, a first metal coating layer 20 and a second metal coating layer 30. The first metal coating layer 20 and the second metal coating layer 30 are made of materials different from one another, and are formed on the substrate 10 by different processes.

The substrate 10 can be made of copper or aluminum, but can also be made of copper alloy or aluminum alloy. In addition, the substrate 10 can have a plurality of fins 11. In the present embodiment, the fins 11 can be integrally formed on the substrate 10. Furthermore, the fins 11 of the present embodiment are integrally formed on the substrate 10 by mechanical processing, e.g., cutting or grinding. Alternatively, the fins 11 of the present embodiment can be integrally formed on the substrate 10 by forging or by stamping.

Furthermore, the first metal coating layer 20 can be a non-first masking area (i.e., an area outside a first masking area 101 as shown in FIG. 1) formed on the substrate 10 by wet processing. In addition, the first masking area 101 can be formed by printing ink 90 on the substrate 10, by disposing an electroplating tape on the substrate 10, or by disposing a solid and closed jig on the substrate 10. Moreover, multiple ones of the first masking area 101 can be formed by printing the ink 90 on the substrate 10, by disposing the electroplating tapes on the substrate 10, or by disposing the solid and closed jigs on the substrate 10, so that the multiple ones of the first masking area 101 do not have the first metal coating layer 20 formed thereon.

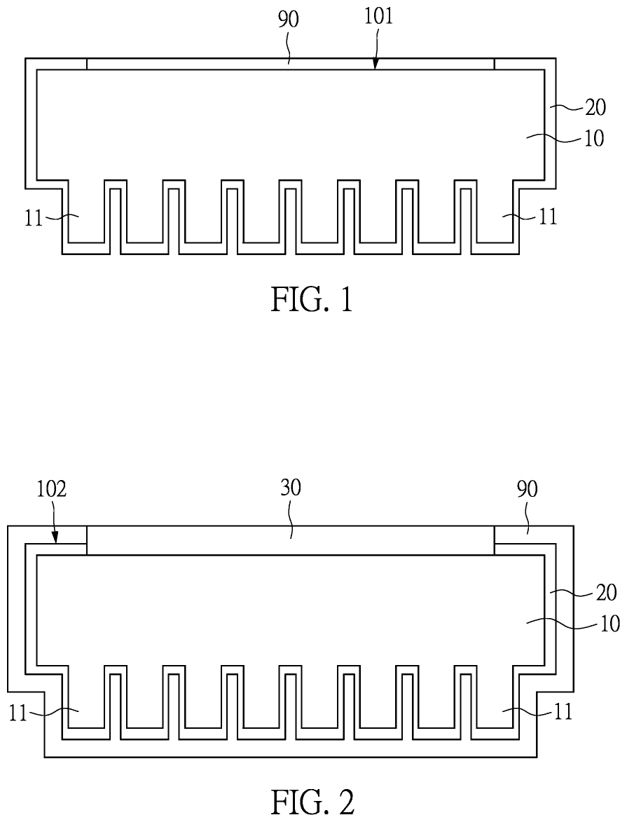

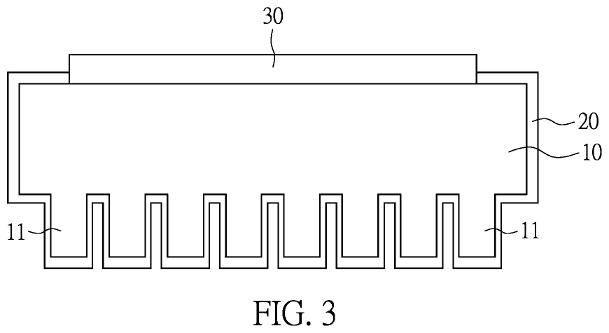

More specifically, the first metal coating layer 20 can be the non-first masking area formed on the substrate 10 by wet processing, such as chemical plating or electroplating. Furthermore, the second metal coating layer 30 can be a non-second masking area (i.e., an area outside a second masking area 102 as shown in FIG. 2) formed on the substrate 10 by sputtering. In addition, the second masking area 102 can be formed by printing the ink 90 on the substrate 10, by disposing the electroplating tape on the substrate 10, or by disposing the solid and closed jig on the substrate 10. Moreover, multiple ones of the second masking area 102 can be formed by printing the ink 90 on the substrate 10, by disposing the electroplating tapes on the substrate 10, or by disposing the solid and closed jigs on the substrate 10, so that the multiple ones of the second masking area 102 do not have the second metal coating layer 30 formed thereon. The first masking area 101 and the second masking area 102 are not necessarily the same. In addition, the first masking area 101 and the second masking area 102 do not necessarily overlap each other, and the first masking area 101 and the second masking area 102 can be sequentially formed.

In the present embodiment, the first metal coating layer 20 can be formed by chemically plating or electroplating a single metal. The signal metal can be nickel, copper, silver, or gold. Therefore, the first metal coating layer 20 can be a chemically plated or an electroplated nickel layer, a chemically plated or an electroplated copper layer, a chemically plated or an electroplated silver layer, or a chemically plated or an electroplated gold layer. Accordingly, through forming the first metal coating layer 20 on the substrate 10, an oxidation resistance and the aesthetics of the substrate 10 can be effectively increased.

In certain embodiments, the first metal coating layer 20 can be formed by chemically plating or electroplating alloy metal. The alloy metal can be nickel alloy, copper alloy, silver alloy, or gold alloy. Therefore, the first metal coating layer 20 can also be a chemically plated or an electroplated nickel alloy layer, a chemically plated or an electroplated copper alloy layer, a chemically plated or an electroplated silver alloy layer, or a chemically plated or an electroplated gold alloy layer.

In the present embodiment, the second metal coating layer 30 can be formed by sputtering the single metal. The single metal can be nickel, copper, silver, or gold. Therefore, the second metal coating layer 30 can be a sputtered nickel layer, a sputtered copper layer, a sputtered silver layer, or a sputtered gold layer, such that the second metal coating layer 30 can have a corrosion resistance property, a soldering ability, or a sintering ability. In addition, a predetermined pattern can be provided in the second metal coating layer 30 for further processing (e.g., soldering). A thickness of the second metal coating layer 30 is preferably between 1 μm and 5 μm, so that the second metal coating layer 30 has an extremely thin thickness. In addition, the second metal coating layer 30 can be formed by performing an ultra high vacuum (UHV) sputtering process on the single metal, so as to increase an adhesion of the second metal coating layer 30 and decrease a probability of contamination.

In certain embodiments, the second metal coating layer 30 can be formed by sputtering the alloy metal. The alloy metal can be nickel alloy, copper alloy, silver alloy, or gold alloy. Therefore, the second metal coating layer 30 can also be a sputtered nickel alloy layer, a sputtered copper alloy layer, a sputtered silver alloy layer, or a sputtered gold alloy layer.

### Second Embodiment

Reference is made to FIG. 4, in which a second embodiment of the present disclosure is shown. The second embodiment of the present disclosure provides a radiator structure. The radiator structure of the present embodiment is substantially the same as that of the first embodiment. The difference between the present embodiment and the first embodiment is that, the first metal coating layer 20 can be formed on a surface of the substrate 10 (i.e., the non-first masking area) by chemical plating or electroplating, so that the second metal coating layer 30 can be the non-second masking area (i.e., the area outside the second masking area 102) formed on the first metal coating layer 20 of the substrate 10 by sputtering.

### Third Embodiment

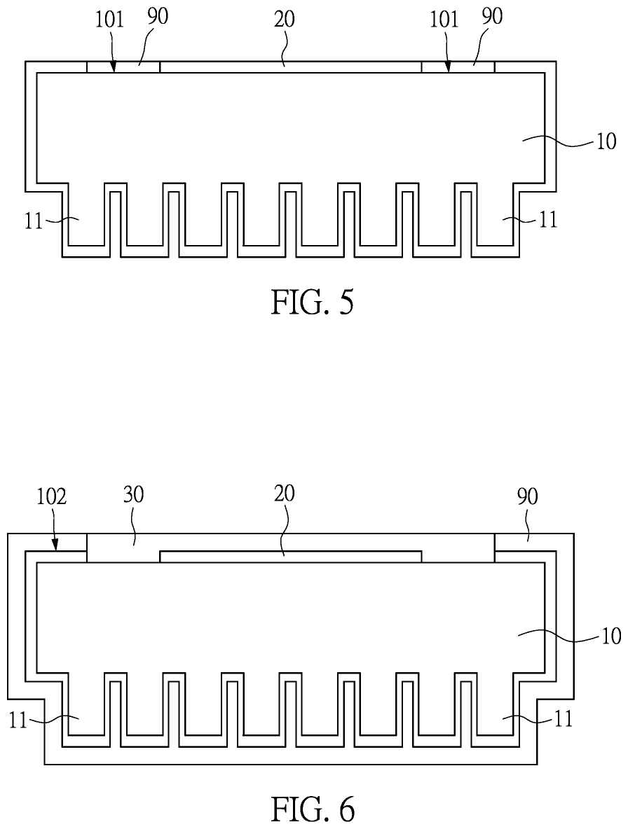

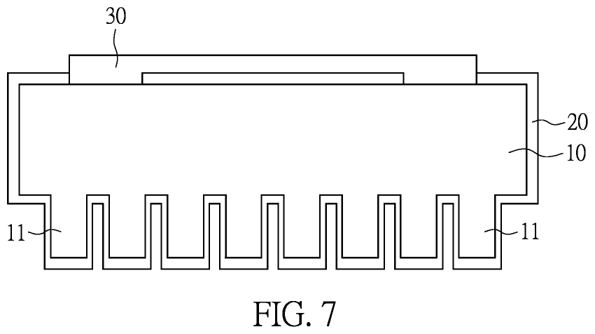

Reference is made to FIG. 5 to FIG. 7, in which a third embodiment of the present disclosure is shown. The third embodiment of the present disclosure provides a radiator structure. The radiator structure of the present embodiment is substantially the same as that of the first embodiment. The difference between the present embodiment and the first embodiment is that, the first metal coating layer 20 can be a non-masking area (i.e., an area outside the first masking area 101 as shown in FIG. 5) formed on the substrate 10 by chemical plating or electroplating, so that the second metal coating layer 30 can be a non-masking area (i.e., an area outside the second masking area 102 as shown in FIG. 6) correspondingly formed on the substrate 10 and the first metal coating layer 20 by sputtering.

### Fourth Embodiment

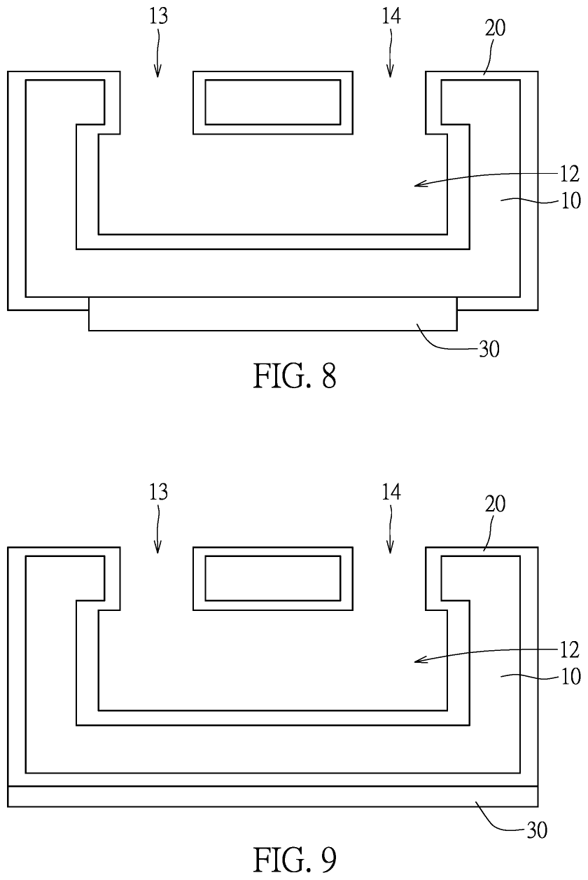

Referring to FIG. 8, in which a fourth embodiment of the present disclosure is shown, the fourth embodiment of the present disclosure provides a radiator structure. The radiator structure of the present embodiment is substantially the same as that of the first embodiment. The difference between the present embodiment and the first embodiment is that, the substrate 10 has a cavity 12, and a water inlet 13 and a water outlet 14 that are correspondingly connected to the cavity 12.

The first metal coating layer 20 is the non-first masking area (i.e., the area outside the first masking area) formed on an inner surface and an outer surface of the substrate 10 by chemical plating or electroplating, so that the first metal coating layer 20 is formed on a wall surface of the cavity 12, a periphery of the water inlet 13, and a periphery of the water outlet 14. Accordingly, the second metal coating layer 30 can be the non-second masking area (i.e., the area outside the second masking area) formed on the outer surface of the substrate 10 by sputtering. Therefore, through forming the first metal coating layer 20 on the wall surface of the cavity 12, the periphery of the water inlet 13, and the periphery of the water outlet 14, oxidation and rust formation on the substrate 10 can be effectively prevented. In addition, through forming the second metal coating layer 30 on the outer surface of the substrate 10, the soldering ability or the sintering ability thereof can be effectively increased.

### Fifth Embodiment

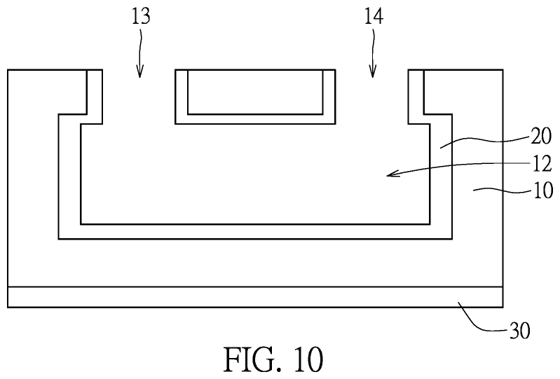

Reference is made to FIG. 9, in which a fifth embodiment of the present disclosure is shown. The fifth embodiment of the present disclosure provides a radiator structure. The radiator structure of the present embodiment is substantially the same as that of the fourth embodiment. The difference between the present embodiment and the fourth embodiment is that, the first metal coating layer 20 can be formed on the inner surface and the outer surface of the substrate 10 (i.e., the non-first masking area) by chemical plating or electroplating, so that the second metal coating layer 30 can be the non-second masking area (i.e., the area outside the second masking area) formed on the first metal coating layer 20 of the outer surface of the substrate 10 by sputtering.

### Sixth Embodiment

Reference is made to FIG. 10, in which a sixth embodiment of the present disclosure is shown. The sixth embodiment of the present disclosure provides a radiator structure. The radiator structure of the present embodiment is substantially the same as that of the fifth embodiment. The difference between the present embodiment and the fifth embodiment is that, the first metal coating layer 20 can be formed on the wall surface of the cavity 12, the periphery of the water inlet 13, and the periphery of the water outlet 14 in the substrate 10 (i.e., the non-first masking area) by chemical plating or electroplating, so that the second metal coating layer 30 can be the non-second masking area (i.e., the area outside the second masking area) formed on the outer surface of the substrate 10 by sputtering. In addition, the substrate 10 can have multiple ones of the cavity 12.

### Beneficial Effects of the Embodiments

In conclusion, in the radiator structure provided by the present disclosure, by virtue of “the first metal coating layer 20 and the second metal coating layer 30 being made of materials different from one another, and being formed on the substrate 10 by different processes”, “the first metal coating layer 20 being the non-first masking area formed on the substrate 10 by wet processing”, and “the second metal coating layer 30 being the non-second masking area correspondingly formed on the first metal coating layer 20 and the substrate 10 by sputtering, and the first masking area 101 and the second masking area 102 being not necessarily the same”, the oxidation resistance and the aesthetics of the radiator structure can be effectively increased. Further, the corrosion resistance property, the soldering ability, and/or the sintering ability of the radiator structure can be improved, thereby increasing a product life cycle thereof.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

1. A radiator structure, comprising:
a substrate, a first metal coating layer, and a second metal coating layer, wherein the first metal coating layer and the second metal coating layer are made of materials different from one another, and are formed on the substrate by different processes;
wherein the first metal coating layer is a non-first masking area formed on the substrate by wet processing, the second metal coating layer is a non-second masking area correspondingly formed on the substrate by sputtering, and a first masking area and a second masking area are not necessarily the same;
wherein the second metal coating layer is sputtered on the substrate to have a desired ultra-thin thickness of 1 μm to 5 μm, so as to improve sintering ability, and the second metal coating layer is a sputtered silver alloy layer, so as to connect with a heat source by silver sintering.

2. The radiator structure according to claim 1, wherein the substrate is made of copper, aluminum, copper alloy, or aluminum alloy.

3. The radiator structure according to claim 1, wherein the first metal coating layer is made of nickel, nickel alloy, copper, copper alloy, silver, silver alloy, gold, or gold alloy.

4. The radiator structure according to claim 1, wherein the first metal coating layer is formed on a surface of the substrate by chemical plating or electroplating.

5. The radiator structure according to claim 1, wherein the first masking area is formed by arranging a jig on the substrate, by arranging an electroplating tape on the substrate, or by printing ink on the substrate, so that the first metal coating layer is not formed on the first masking area.

6. (canceled)

7. The radiator structure according to claim 1, wherein the second masking area is formed by arranging a jig on the substrate or the first metal coating layer, by arranging an electroplating tape on the substrate or the first metal coating layer, or by printing ink on the substrate or the first metal coating layer, so that the second metal coating layer is not formed on the second masking area.

8. (canceled)

9. The radiator structure according to claim 1, wherein the substrate has at least one cavity, a water inlet and a water outlet, and the water inlet and the water outlet are correspondingly connected to the at least one cavity.

10. The radiator structure according to claim 9, wherein the first metal coating layer is correspondingly formed on a wall surface of the at least one cavity, a periphery of the water inlet, and a periphery of the water outlet.

11. A radiator structure, comprising:
a substrate, a first metal coating layer, and a second metal coating layer, wherein the first metal coating layer and the second metal coating layer are made of materials different from one another, and are formed on the substrate by different processes;
wherein the first metal coating layer is a non-first masking area formed on the substrate by wet processing, the second metal coating layer is a non-second masking area correspondingly formed on the first metal coating layer by sputtering, and a first masking area and a second masking area are not necessarily the same;
wherein the second metal coating layer is sputtered on the first metal coating layer to have a desired ultra-thin thickness of 1 μm to 5 μm, so as to improve sintering ability, and the second metal coating layer is a sputtered silver alloy layer, so as to connect with a heat source by silver sintering.

12. A radiator structure, comprising:
a substrate, a first metal coating layer, and a second metal coating layer, wherein the first metal coating layer and the second metal coating layer are made of materials different from one another, and are formed on the substrate by different processes;
wherein the first metal coating layer is a non-first masking area formed on the substrate by wet processing, the second metal coating layer is a non-second masking area correspondingly partially formed on the substrate and the first metal coating layer by sputtering, and a first masking area and a second masking area are not necessarily the same;
wherein the second metal coating layer is sputtered on the substrate and the first metal coating layer to have a desired ultra-thin thickness of 1 μm to 5 μm, so as to improve sintering ability, and the second metal coating layer is a sputtered silver alloy layer, so as to connect with a heat source by silver sintering.
